(19) United States
(12) Patent Application Publication
(10) Pub. No.: US 2005/0098336 A1
(43) Pub. Date: May 12, 2005

(54) Static electricity control bonding ground clamps

(76) Inventor: Raymond Leon JR., La Quinta, CA (US)

Correspondence Address: Raymond Leon Jr., 78-810 Wakefield Circle, La Quinta, CA, 92253, US

(21) Appl. No.: 10/940,871

(22) Filed: Sep. 13, 2004

Related U.S. Application Data
(60) Provisional application No. 60/502,470, filed on Sep. 12, 2003.

(51) Int. Cl. H05K 9/00

(52) U.S. Cl. 174/35 R

(57) ABSTRACT

A first magnetic clamp embodiment (20) for bonding gas pipes or objects that need static electricity control object (13), includes a first and second magnetic members having poles consisting of parallel magnetic plains (10) and (11). A wire or conductor (12) connecting both magnetic members. A second magnetic clamp embodiment (220) for bonding gas pipe fittings or objects that need static electricity control, includes one magnetic member having poles consisting of parallel magnetic plains (20) a grounding rod (22) connected with a wire or conductor (21).

### TECHNICAL FIELD

The present invention pertains generally to bonding and grounding ground clamps in particular to magnetic bonding and grounding ground clamps that attach to magnetic objects.

### BACKGROUND ART

When one works in the natural gas industry and in particular when repairing gas pipes One encounters static electricity. Static electricity is caused by friction. In the process of repairing gas pipe one must cut out the corroded or damaged piece of pipe and replace it with a new pipe. Cutting the pipe causes friction and can produce dangerous sparks. The purpose of the present invention is to keep the pipes bonded at all times during cutting as cutting produces friction in particular gas pipes. By keeping them connected at all times prevents static electricity thus preventing an explosion.

Also, in the natural gas industry and in particular when repairing gas fittings one encounters static electricity. When changing fittings, friction is applied so One must ground the fittings. The second embodiment of this invention keeps pipes grounded to the Earth thus preventing a spark and an explosion. Both of the embodiments of this invention will attach to magnetic flat and round objects, small or large.

### DISCLOSURE OF INVENTION

The present invention is directed to the repair of natural gas pipes being that they are round makes it difficult to attach flat magnet to round pipe. The advantage of this present invention is that it has two magnetic pieces that have parallel poles thus can easily attach to round objects, the two pieces are connected with a wire to allow continuity on all three pieces.

The advantage of the second embodiment of this invention is that it has one magnetic piece that has parallel poles also and can easily attach to round objects, this magnetic member is connected to a ground rod with a conductor giving continuity on all three pieces. The magnetic member is attached to the object that needs static electricity prevention and the ground rod is attached to the Earth.

Herein are two embodiments of the present invention.

### BRIEF DESCRIPTION OF PICTURES

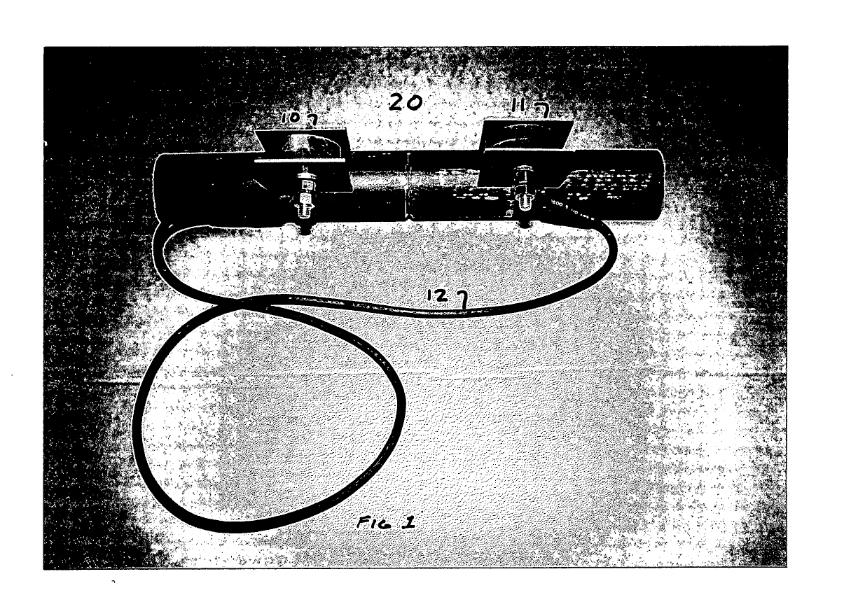

FIG. 1 is a view of the bonding clamp

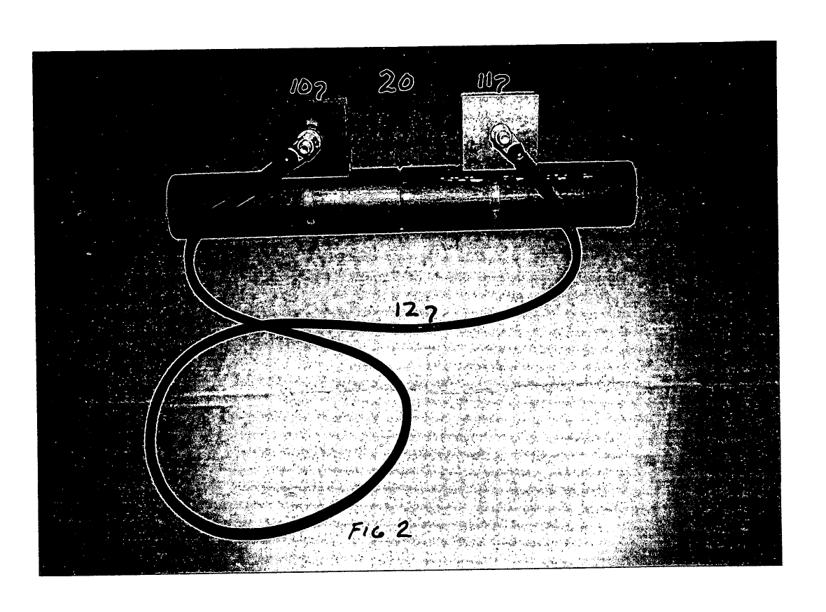

FIG. 2 is a view of the bonding clamp attached to pipes

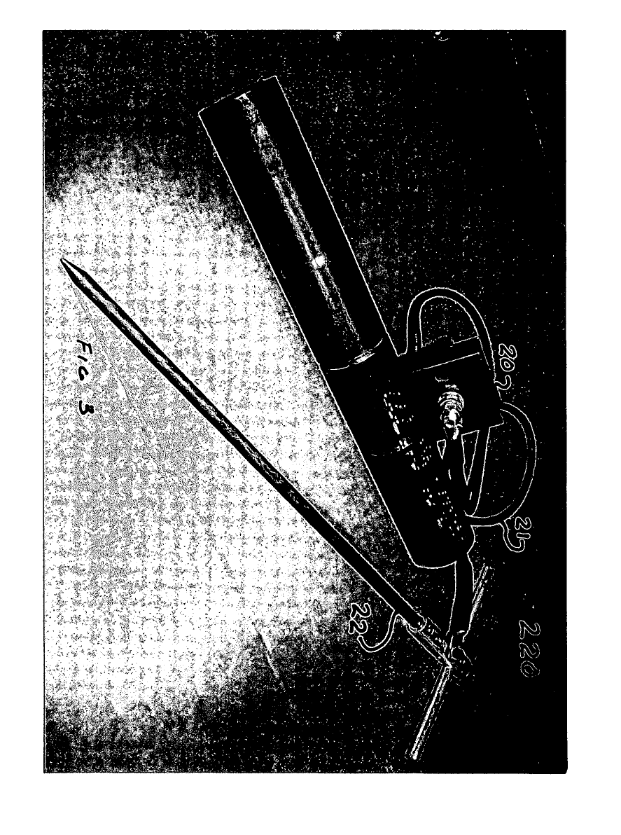

FIG. 3 is a view of the purging clamp

### MODES OF CARRYING OUT THE INVENTION

Referring to FIG. 1 there is a view respectively of a magnetic bonding clamp for bonding magnetic objects in accordance with the present invention, generally designated as 20. Magnetic clamp 20 includes two magnetic pieces 10 and 11 with parallel magnetic poles. Both pieces are connected with a wire 12.

Referring to FIG. 2 there is a view respectively of a magnetic bonding clamp for bonding magnetic objects in accordance with the present invention, generally designated as 20. Magnetic clamp 20 is attached with two magnetic pieces 10 and 11 with parallel magnetic poles to pipe 13. All pieces are connected with a wire 12.

Referring to FIG. 3 there is a view respectively of a magnetic bonding clamp for bonding magnetic objects in accordance with the present invention, generally designated as 220. Magnetic clamp 220 includes one magnetic piece 20 with parallel magnetic poles. A ground rod 22 is attached to the magnetic piece with a wire 21.

The preferred embodiments of the invention described herein are exemplary and numerous modification, dimensional variations, and rearrangements can be readily envisioned to achieve an equivalent result, all of which are intended to be embraced within the scope of the appended claims.

1. A magnetic bonding device comprising:
a first magnetic member with parallel poles
a second magnetic member with parallel poles
a connecting conductor.

2. A magnetic bonding device according to claim 1, further including:
said first and second magnetic members having poles consisting of parallel magnetic plains.

3. A magnetic bonding device comprising:
a magnetic member with parallel poles
a grounding rod
a connecting conductor.

4. A magnetic bonding device according to claim 3, further including:
said magnetic member having poles consisting of parallel magnetic plains.
